(19) United States
(12) Patent Application Publication
(10) Pub. No.: US 2026/0107492 A1
(43) Pub. Date: Apr. 16, 2026

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Suzhou, Jiangsu (CN)

(72) Inventors: Yang LIU, Suzhou, Jiangsu (CN); Ziming DU, Suzhou, Jiangsu (CN); Jheng-Sheng YOU, Suzhou, Jiangsu (CN)

(73) Assignee: INNOSCIENCE (SUZHOU) SEMICONDUCTOR CO., LTD., Suzhou, Jiangsu (CN)

(21) Appl. No.: 19/112,266

(22) PCT Filed: Sep. 21, 2022
(86) PCT No.: PCT/CN2022/120122

§ 371 Date: Mar. 17, 2025

(51) Int. Cl. H10D 30/47; H10D 30/01; H10W 20/42

(52) U.S. Cl. CPC H10D 30/475; H10D 30/015; H10W 20/422

(57) ABSTRACT

A nitride-based semiconductor device includes a first nitride-based semiconductor layer, a second nitride-based semiconductor layer, a gate electrode, and a first dielectric layer. The second nitride-based semiconductor layer is disposed on the first nitride-based semiconductor layer. The second nitride-based semiconductor layer has a bandgap higher than a bandgap of the first nitride-based semiconductor layer. The gate electrode is disposed above the second nitride-based semiconductor layer. The first dielectric layer is disposed above the gate electrode and has a top surface, a side surface and an inclined surface. The inclined surface connects the top surface to the side surface, and a connection interface between the inclined surface and the side surface is above the gate electrode.

### CROSS-REFERENCE TO RELATED APPLICATIONS

This application is a national stage of international PCT application No. PCT/CN2022/120122 filed on Sep. 21, 2022, the entire contents of which are incorporated herein by reference.

### FIELD

The present disclosure generally relates to a nitride-based semiconductor device. More specifically, the present disclosure relates to a nitride-based semiconductor device having a dielectric layer with a chamfer structure.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY

In accordance with one aspect of the present disclosure, a semiconductor device is provided. A nitride-based semiconductor device includes a first nitride-based semiconductor layer, a second nitride-based semiconductor layer, a gate electrode, and a first dielectric layer. The second nitride-based semiconductor layer is disposed on the first nitride-based semiconductor layer. The second nitride-based semiconductor layer has a bandgap higher than a bandgap of the first nitride-based semiconductor layer. The gate electrode is disposed above the second nitride-based semiconductor layer. The first dielectric layer is disposed above the gate electrode and has a top surface, a side surface and an inclined surface. The inclined surface connects the top surface to the side surface, and a connection interface between the inclined surface and the side surface is above the gate electrode.

In accordance with one aspect of the present disclosure, a semiconductor device is provided. A nitride-based semiconductor device includes a first nitride-based semiconductor layer, a second nitride-based semiconductor layer, a gate electrode, and a first dielectric layer. The second nitride-based semiconductor layer is disposed on the first nitride-based semiconductor layer. The second nitride-based semiconductor layer has a bandgap higher than a bandgap of the first nitride-based semiconductor layer. The gate electrode is disposed above the second nitride-based semiconductor layer. The first dielectric layer is disposed above the gate electrode and has a chamfer structure that is located immediately over the gate electrode.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A gate electrode is formed over the second nitride-based semiconductor layer. A first dielectric layer is formed to cover the gate electrode and the second nitride-based semiconductor layer, in which this step further includes sub-steps as follows. A blanket dielectric layer is formed to cover the gate electrode and the second nitride-based semiconductor layer. A blanket dielectric layer is formed to cover the gate electrode and the second nitride-based semiconductor layer. The blanket dielectric layer is patterned to form a through hole directly over the gate electrode. An ion bombardment process is performed on a portion of the blanket dielectric layer adjacent to the through hole, such that the portion is formed to have an inclined surface, thereby forming the first dielectric layer.

By the above configuration, in embodiments of the present disclosure, an inclined surface is formed between a top and a side surface of the dielectric layer, such that an accommodating space defined by the top, side and the inclined surfaces can have a funnel shape. The contact via can be formed/disposed in the funnel-shaped accommodating space, so the stress generated by the material difference between the contact via and the dielectric layer can be relieved, thereby avoiding an open circuit issue. Also, the contact resistance of the semiconductor device can be reduced due to the stress relieved. As such, the semiconductor device can have good reliability and good electrical properties.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a top view of a semiconductor device according to some embodiments of the present disclosure;

FIG. 1B is a vertical cross-sectional view of the semiconductor device along the line I-I′ in the FIG. 1A;

FIG. 1C is a vertical cross-sectional view of an enlarged region A of the semiconductor device 1A;

FIG. 2A, FIG. 2B, FIG. 2C, and FIG. 2D show different stages of a method for manufacturing a nitride-based semiconductor device according to some embodiments of the present disclosure;

FIG. 3 is a vertical cross-sectional view of an enlarged region of a semiconductor device according to some embodiments of the present disclosure; and

FIG. 4 is a vertical cross-sectional view of an enlarged region of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

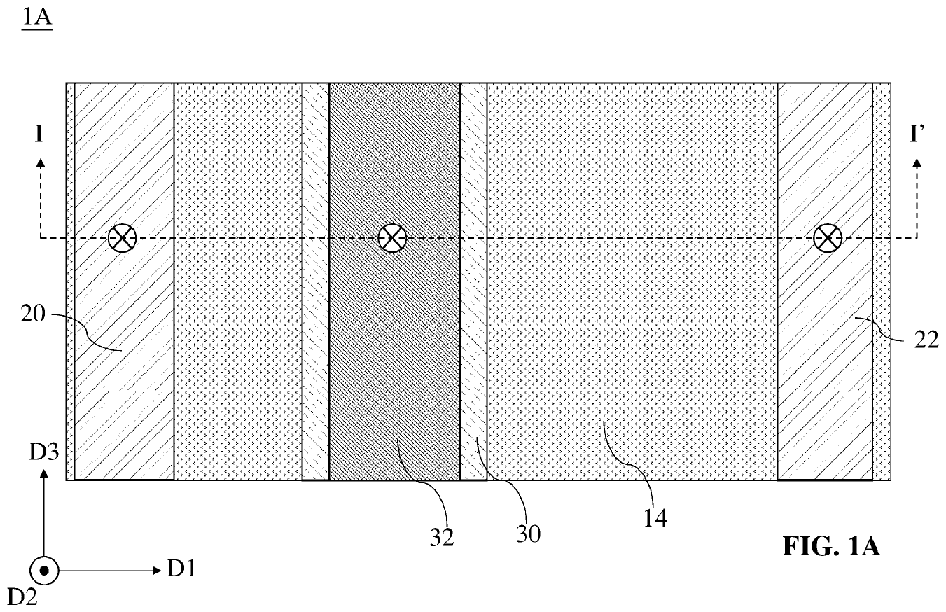

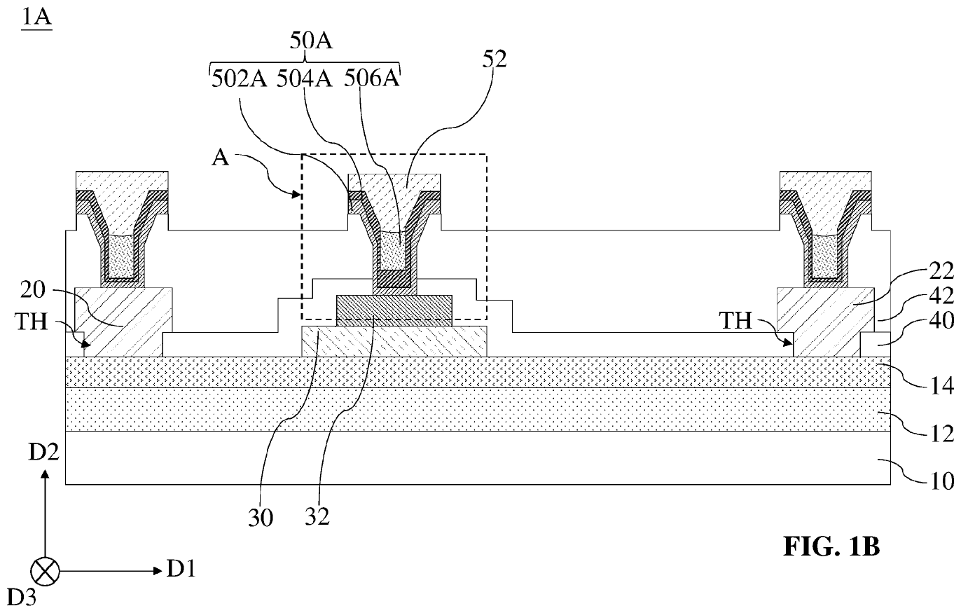

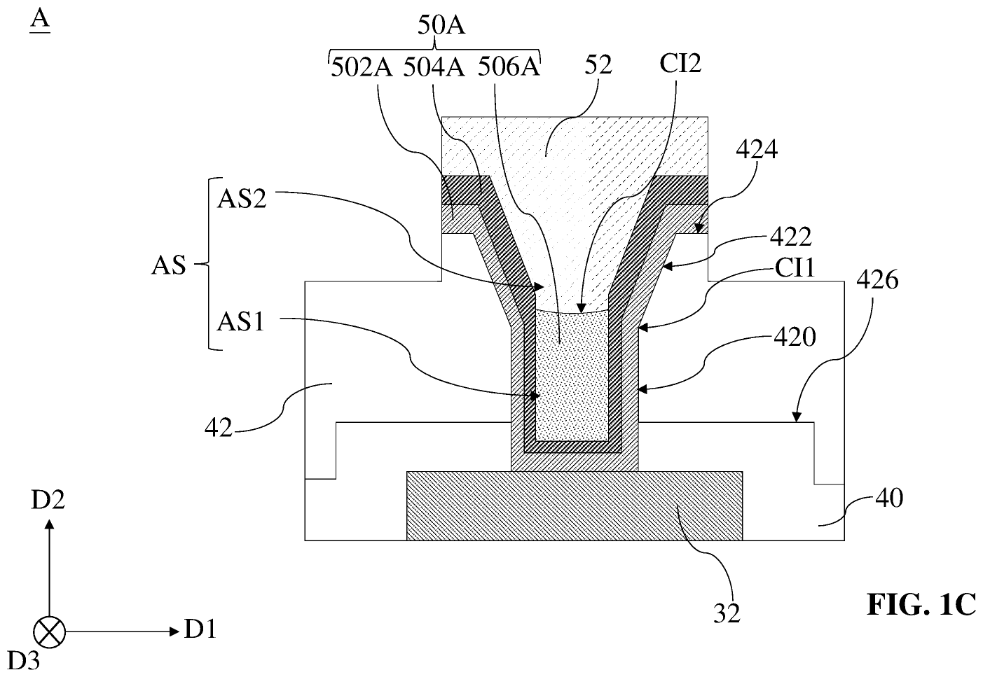

FIG. 1A is a top view of a semiconductor device 1A according to some embodiments of the present disclosure. FIG. 1B is a vertical cross-sectional view of the semiconductor device 1A along the line I-I′ in the FIG. 1A. The directions D1, D2 and D3 are labeled in the FIGS. 1A and 1B, in which the directions D1, D2 and D3 are different from each other. The directions D1 to D3 are perpendicular to each other.

The semiconductor device 1A includes a substrate 10, nitride-based semiconductor layers 12, 14, electrodes 20, 22, a doped nitride-based layer 30, a gate electrode 32, a plurality of dielectric layers 40,42, a plurality of contact vias 50A, and a circuit layer 52.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

A buffer layer (not shown) can be disposed on/over/above the substrate 10. The buffer layer can be disposed between the substrate 10 and the nitride-based semiconductor layer 12. The buffer layer can be configured to reduce lattice and thermal mismatches between the substrate 10 and the nitride-based semiconductor layer 12, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof.

In some embodiments, the semiconductor device 1A may further include a nucleation layer (not shown). The nucleation layer may be formed between the substrate 10 and the buffer layer. The nucleation layer can be configured to provide a transition to accommodate a mismatch/difference between the substrate 10 and a III-nitride layer of the buffer layer. The exemplary material of the nucleation layer can include, for example but is not limited to AlN or any of its alloys.

The nitride-based semiconductor layer 12 can be disposed on/over/above the substrate 10. The nitride-based semiconductor layer 14 can be disposed on/over/above the nitride-based semiconductor layer 12. The exemplary materials of the nitride-based semiconductor layer 12 can include, for example but are not limited to, nitrides or group III-V compounds, such as GaN, AlN, InN, InₓAl_{y}Ga_{(1-x-y)}N where x+y≤1, AlₓGa₍₁₋ₓ₎N, where x≤1. The exemplary materials of the nitride-based semiconductor layer 14 can include, for example but are not limited to, nitrides or group III-V compounds, such as GaN, AlN, InN, InₓAl_{y}Ga_{(1-x-y)}N where x+y≤1, Al_{y}Ga_{(1-y)}N, where y≤1.

The exemplary materials of the nitride-based semiconductor layers 12 and 14 are selected such that the nitride-based semiconductor layer 14 has a bandgap (i.e., forbidden band width) greater/higher than a bandgap of the nitride-based semiconductor layer 12, which causes electron affinities thereof different from each other and forms a heterojunction therebetween. For example, when the nitride-based semiconductor layer 14 is an AlGaN layer having bandgap of approximately 4.0 eV, the nitride-based semiconductor layer 12 can be selected as an undoped GaN layer having a bandgap of approximately 3.4 eV. As such, the nitride-based semiconductor layers 12 and 14 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The electrodes 20 and 22 can be disposed on/over/above the nitride-based semiconductor layer 14. The electrodes 20 and 22 are directly in contact with the nitride-based semiconductor layer 14. Referring to the FIG. 1A, the electrodes 20 and 22 can extend along the direction D3, such that each of the electrodes 20 and 22 can have a strip profile. In some embodiments, the electrode 20 can serve as a source electrode. In some embodiments, the electrode 20 can serve as a drain electrode. In some embodiments, the electrode 22 can serve as a source electrode. In some embodiments, the electrode 22 can serve as a drain electrode. The role of the electrodes 20 and 22 depends on the device design.

In some embodiments, the electrodes 20 and 22 can include, for example but are not limited to, metals, alloys, doped semiconductor materials (such as doped crystalline silicon), compounds such as silicides and nitrides, other conductor materials, or combinations thereof. The exemplary materials of the electrodes 20 and 22 can include, for example but are not limited to, Ti, AlSi, TiN, or combinations thereof.

Each of the electrodes 20 and 22 may be a single layer, or plural layers of the same or different composition. The electrodes 20 and 22 form ohmic contacts with the nitride-based semiconductor layer 14. Furthermore, the ohmic contacts can be achieved by applying Ti, Al, or other suitable materials to the electrodes 20 and 22. In some embodiments, each of the electrodes 20 and 22 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped nitride-based semiconductor layer 30 is disposed on/over/above the nitride-based semiconductor layer 14. The doped nitride-based semiconductor layer 30 is in contact with the nitride-based semiconductor layer 14. The gate electrode 32 is disposed on/over/above the doped nitride-based semiconductor layer 30 and the nitride-based semiconductor layer 14. The gate electrode 32 is in contact with the doped nitride-based semiconductor layer 30. The doped nitride-based semiconductor layer 30 is disposed between the gate electrode 32 and the nitride-based semiconductor layer 14. Each of the doped nitride-based semiconductor layer 30 and the gate electrode 32 extends along the direction D3 to have a strip profile.

The gate electrode 32 is narrower than the doped nitride-based semiconductor layer 30 at the D1 direction. In some embodiments, a width of the doped nitride-based semiconductor layer 30 is substantially the same as a width of the gate electrode 32 at the D3 direction. The profiles of the doped nitride-based semiconductor layer 30 and the gate electrode 32 are the same, for example, both of them are rectangular profiles. In other embodiments, the profiles of the doped nitride-based semiconductor layer 30 and the gate electrode 32 can be different from each other. For example, the profile of the doped nitride-based semiconductor layer 30 can be a trapezoid profile, the profile of the gate electrode 32 can be a rectangular profile.

In the exemplary illustration of FIG. 1B, the semiconductor device 1A is an enhancement mode device, which is in a normally-off state when the gate electrode 32 is at approximately zero bias. Specifically, the doped nitride-based semiconductor layer 30 may create at least one p-n junction with the nitride-based semiconductor layer 14 to deplete the 2DEG region, such that at least one zone of the 2DEG region corresponding to a position below the corresponding the gate electrode 32 has different characteristics (e.g., different electron concentrations) than the rest of the 2DEG region and thus is blocked. Due to such mechanism, the semiconductor device 1A has a normally-off characteristic. In other words, when no voltage is applied to the gate electrode 32 or a voltage applied to the gate electrode 32 is less than a threshold voltage (i.e., a minimum voltage required to form an inversion layer below the gate electrode 32), the zone of the 2DEG region below the gate electrode 32 is kept blocked, and thus no current flows therethrough.

In some embodiments, the doped nitride-based semiconductor layer 30 can be omitted, such that the semiconductor device 1A is a depletion-mode device, which means the semiconductor device 1A in a normally-on state at zero gate-source voltage.

The doped nitride-based semiconductor layer 30 can be a p-type doped III-V semiconductor layer. The exemplary materials of the doped nitride-based semiconductor layer 30 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Zn, Cd, and Mg. In some embodiments, the nitride-based semiconductor layer 14 includes undoped GaN and the nitride-based semiconductor layer 12 includes AlGaN, and the doped nitride-based semiconductor layer 30 is a p-type GaN layer which can bend the underlying band structure upwards and to deplete the corresponding zone of the 2DEG region, so as to place the semiconductor device 1A into an off-state condition.

The exemplary materials of the gate electrode 32 may include metals or metal compounds. The gate electrode 32 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The dielectric layer 40 is disposed on/over/above the nitride-based semiconductor layer 14, the doped nitride-based semiconductor layer 30 and the gate electrode 32. The dielectric layer 40 covers the doped nitride-based semiconductor layer 30 and the gate electrode 32 to form a protruding portion. The dielectric layer 40 has a plurality of through holes TH. The electrodes 20 and 22 can penetrate the dielectric layer 40 via the through holes TH to make contact with the nitride-based semiconductor layer 14.

In general, with respect to a semiconductor device, a through hole within a dielectric layer is usually filled with a conductive material to achieve electrical connection between layers. However, since thermal expansion coefficients of the conductive material and the dielectric material are different, a thermal stress might be generated at an interface therebetween, resulting in uneven stress distribution in the conductive material. The affection is more obvious at a condition that the dielectric layer has a right angle for defining the through hole. Accordingly, cracks can be generated inside the conductive material, resulting in an opening circuit issue

At least to avoid the afore-mentioned issues, the present disclosure is to provide a novel structure for the nitride-based semiconductor devices.

FIG. 1C is a vertical view of an enlarged region A of the semiconductor device 1A. Referring to FIG. 1B and FIG. 1C, during the formation of the dielectric layer 42, first of all, a patterning process is performed on a blanket dielectric layer for forming a through hole with a right angle. The patterning process can include a dry etching process. After that, an ion bombardment process is performed on a portion of the blanket dielectric layer adjacent to the through hole, such that the portion is formed to have an inclined surface (i.e., chamfer structure).

The dielectric layer 42 is formed to be disposed on/over/above the gate electrode 32. The dielectric layer 42 is formed to be disposed on/over/above the electrodes 20 and 22. The dielectric layer 42 is formed to cover the dielectric layer 40. The dielectric layer 40 is located between the dielectric layer 42 and the nitride-based semiconductor layer 14.

The dielectric layer 42 is formed to have a side surface 420, an inclined surface 422, a top surface 424, and a bottom surface 426. The inclined surface 422 is located immediately over the gate electrode 32. The inclined surface 422 and the side surface 420 are located between the top surface 424 and the bottom surface 426. The inclined surface 422 connects the top surface 424 to the side surface 420. The side surface 420 connects the inclined surface 422 to the bottom surface 426. The side surface 420 and the inclined surface 422 have different surface roughnesses due to different manufacturing processes thereof (i.e., dry etching process and ion bombardment process). In some embodiments, the side surface 420 is formed by an etching process, and the inclined surface 422 is formed by an etching process in combination with an ion bombardment process.

A connection interface CI1 is formed between the inclined surface 422 and the side surface 420. The connection interface CI1 is directly above the gate electrode 32. Orthogonal/vertical projections of the side surface 420 and the inclined surface 422 on the nitride-based semiconductor layer 14 are within an orthogonal/vertical projection of the gate electrode 32 on the nitride-based semiconductor layer 14.

The side surface 420 defines the accommodating space AS1, and the inclined surface 422 defines the accommodating space AS2. The accommodating space AS2 communicates with the accommodating space AS1. The side surface 420 and the inclined surface 422 have different extending depths. Specifically, the extending depth of the side surface 420 is greater than that of the inclined surface 422, such that the depth of the accommodating space AS1 is greater than that of the accommodating space AS2. At the D1 direction, a width of the accommodating space AS2 gradually decreases along a direction from the top surface 424 toward the bottom surface 426 of the dielectric layer 42. A width of the accommodating space AS1 is constant.

Overall, the two accommodating spaces AS1 and AS2 can be viewed as an accommodating space AS. The accommodating space AS, which is defined by the top, side and the inclined surfaces 424, 420 and 422 of the dielectric layer 42, can have a funnel shape (i.e., Y-shaped).

The profile of the accommodating space AS of the dielectric layer 42 can serve as a buffer to accommodate the difference between the thermal expansion coefficients of the conductive material and the dielectric material, improving the opening circuit issue.

The conductive via 50A can be formed/disposed in the afore-mentioned funnel-shaped accommodating space AS to penetrate the dielectric layer 42. The conductive via 50A can further penetrate the dielectric layer 40, thereby making a contact with the gate electrode 32. The conductive via 50A covers the side surface 420 of the dielectric layer 42. The conductive via 50A covers the inclined surface 422 of the dielectric layer 42. The conductive via 50A covers top surface 424 of the dielectric layer 42.

The conductive via 50A includes two conductive layers 502A, 504A and a conductive filling 506A. The conductive layers 502A, 504A are conformal with a profile constructed by the top surface 424, the inclined surface 422, and the side surface 420 of the dielectric layer 42. Each of the conductive layers 502A and 504A extends from the top surface 424 to the side surface 420 along the inclined surface 422.

Due to conformal configuration, each of the conductive layers 502A and 504A can also have an inclined surface (i.e., chamfer structure) corresponding to the inclined surface 422 of the dielectric layer 42. The inclined surfaces of the conductive layer 502A and 504A are above the gate electrode 32. The conductive filling 506A is wrapped by the conductive layers 502A, 504A. The conductive filling 506A is located at a position lower than the inclined surface of the conductive layer 504A.

With the profile of the dielectric layer 42, even though the stress is generated due to the material differences between the dielectric layer 42 and the conductive via 50A, the stress can be dispersed along an extending direction of the inclined surface 422. As such, the intensity of the stress at the interface between the conductive via 50A and the dielectric layer 42 can be reduced, and thus the phenomenon of the uneven stress distribution would be relieved. As such, the probability of generating cracks in the conductive via 50A can be reduced, thereby avoiding the opening circuit issue. Therefore, the reliability of the semiconductor device 1A can be improved, and the contact resistance thereof can be reduced.

Moreover, with respect to the configuration of the conductive via 50A, at least one of conductive layer 502A/504A is conformal with the profile constructed by the top, the inclined, and the side surfaces 424, 422 and 420 of the dielectric layer 42. Therefore, the stress generated by the conductive layer 502A/504A itself can be adapted to the morphology of the dielectric layer 42. Thus, the negative impacts of the stress can be further reduced. It should be noted that the stress accumulation is enhanced as more layers are formed. Although the multiple layers are formed from different materials and create the stress accumulation, with respect to the conductive via 50A of the present disclosure, the inclined surface 422 can serve as a key point to relieve the stress distribution.

The material of the dielectric layers 40 and 42 can include, for example but are not limited to, dielectric materials. For example, the dielectric layers 40 and 42 can include, for example but are not limited to, SiNₓ, SiOₓ, Si₃N₄, SiON, SiC, SiBN, SiCBN, oxides, nitrides, plasma enhanced oxide (PEOX), or combinations thereof. In some embodiments, each of the dielectric layers 40 and 42 can be a multi-layered structure, such as a composite dielectric layer of Al₂O₃/SiN, Al₂O₃/SiO₂, AlN/SiN, AlN/SiO₂, or combinations thereof.

The exemplary materials of the conductive layers 502A, 504A and conductive filling 506A can include, for example but are not limited to, conductive materials, such as metals or alloys. In some embodiments, the material of the conductive layer 502A can include, for example but are not limited to, titanium (Ti), titanium nitride (TiN), or combinations thereof. In some embodiments, the material of the conductive layer 504A can include, for example but are not limited to, titanium (Ti), titanium nitride (TiN). In some embodiments, the material of the conductive filling 506A can include, for example but are not limited to tungsten (Wu), molybdenum (Mo), copper (Cu), or combinations thereof.

The circuit layer 52 can be disposed on/over/above the conductive via 50A. The circuit layer 52 makes a contact with the inclined surface of the conductive layer 504A. The circuit layer 52 has a bottom portion in contact with the conductive filling 506A. The bottom portion of the circuit layer 52 has a pair of inclined surfaces in contact with the conductive layer 504A and the conductive filling 506A of the conductive via 50A. A contact interface CI2 formed between the bottom portion of the circuit layer 52 and the conductive filling 506A is located at a position lower than the inclined surface of the conductive layer 504A. In some embodiments, the contact interface CI2 can be formed to be a curved surface, such that the curved contact interface CI2 can evenly distribute the stress from the circuit layer 52.

The circuit layer 52 may have metal lines, pads, traces, or combinations thereof, such that the circuit layer 52 can form at least one circuit. The circuit layer 52 can be connected with the gate electrode 32, electrodes 20 and 22 by the contact vias 50A. An external electronic device can send at least one electronic signal to the semiconductor device 1A by the circuit layer 52, and vice versa.

The exemplary materials of the circuit layer 52 can include, for example but are not limited to, conductive materials. The circuit layer 52 may include a single film or multilayered film having Ag, Al, Cu, Mo, Ni, Ti, alloys thereof, oxides thereof, nitrides thereof, or combinations thereof.

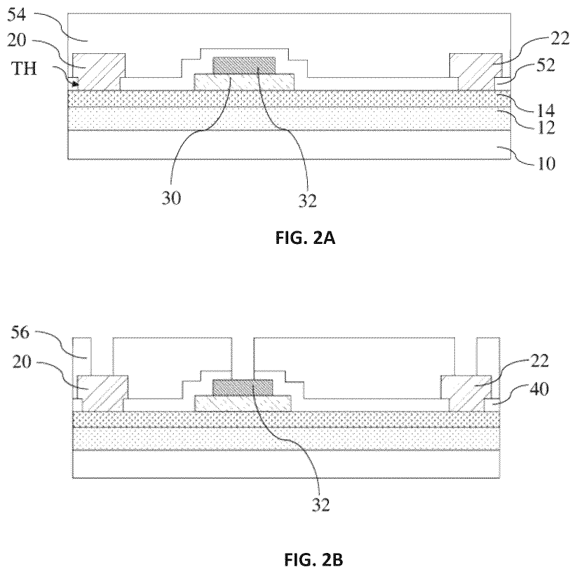

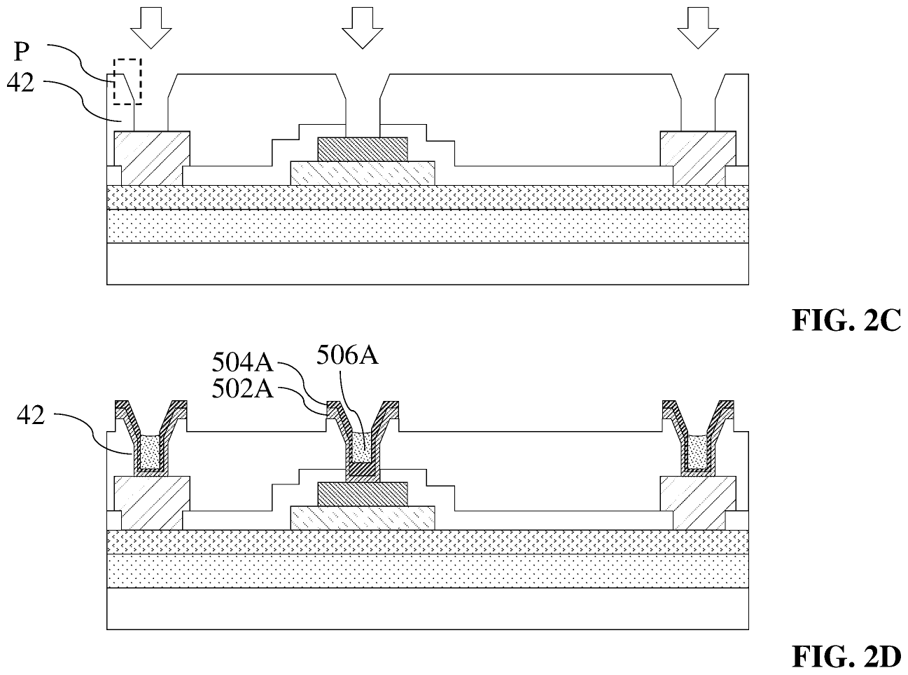

Different stages of a method for manufacturing the semiconductor device 1A are shown in FIG. 2A, FIG. 2B, FIG. 2C, and FIG. 2D, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a nitride-based semiconductor layer 12 is formed on/over/above a substrate 10 by using deposition techniques. A nitride-based semiconductor layer 14 is formed on/over/above the nitride-based semiconductor layer 12 by using deposition techniques, so that a heterojunction is formed therebetween. A doped nitride-based semiconductor layer 30 can be formed on the nitride-based semiconductor layer 14. A gate electrode 32 can be formed on the doped nitride-based semiconductor layer 30.

A blanket dielectric layer (not shown) is formed to cover the nitride-based semiconductor layer 14, the doped nitride-based semiconductor layer 30, and the gate electrode 32. A patterning process is performed on the blanket dielectric layer to form an intermediate dielectric layer 52 with a plurality of through holes TH to expose the nitride-based semiconductor layer 14. The electrodes 20 and 22 can be formed in the through holes TH to make contact with the nitride-based semiconductor layer 14. A blanket dielectric layer 54 is formed over the nitride-based semiconductor layer 14. The blanket dielectric layer 54 is formed to cover the electrodes 20, 22, the gate electrode 32 and the intermediate dielectric layer 52.

The formation of the doped nitride-based semiconductor layer 30, the gate electrode 32, the electrodes 20, 22, and the intermediate dielectric layer 52 includes deposition techniques and a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 2B, a patterning process is performed on the blanket dielectric layer 54 and the intermediate dielectric layer 52, such that a plurality of the through holes can be formed to expose the electrodes 20, 22 and the gate electrode 32. The formed through holes in this stage are directly above the electrodes 20, 22 and the gate electrode 30. After the formation of the through holes, an intermediate dielectric layer 56 and a dielectric layer 40 are formed.

Referring to FIG. 2C, an ion bombardment process is performed on portions P of the intermediate dielectric layer 56 adjacent to the through holes, such that each of the portions P is formed to have an inclined surface, thereby forming a dielectric layer 42. The step of the ion bombardment process includes emission of inert element ions, for example, argon (Ar) ions.

Referring to FIG. 2D, a plurality of conductive layers 502A and 504A are formed to conformally cover the portions P of the dielectric layer 42. In some embodiments, the materials of the conductive layers 502A and 504A can be different from each other as afore mentioned. A conductive filling 506A is formed on the conductive layers 502A and 504A, such that the conductive filling 506A is wrapped by the conductive layers 502A and 504A. Thereafter, the circuit layer 52 can be formed, obtaining the configuration of the semiconductor device 1A as shown in FIGS. 1A, 1B and 1C.

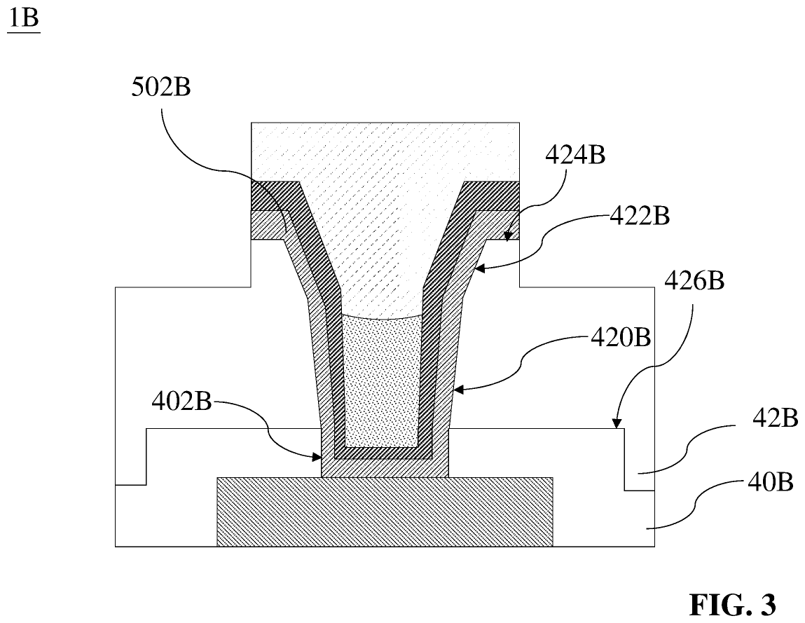

FIG. 3 is a vertical cross-sectional view of an enlarged region of a semiconductor device according to some embodiments of the present disclosure. The semiconductor device 1B is similar to the semiconductor device 1A as described and illustrated with reference to FIGS. 1A, 1B and 1C, except that the dielectric layer 42 is replaced by a dielectric layer 42B. The dielectric layer 42B has a side surface 420B, an inclined surface 422B, and a top surface 424B. The inclined surface 422B connects the side surface 420B to the top surface 424B. The side surface 420B of the dielectric layer 42B is inclined. The slope of the side surface 420B is different from that of the inclined surface 422B. The slope of the side surface 420B is greater than that of the inclined surface 422B. The slope of the side surface 402B of the dielectric layer 40B is greater than that of the side surface 420B of the dielectric layer 42B. With the multistage slope design, the stress at the interface between the conductive layer 502B and the dielectric layer 42B can be more evenly distributed.

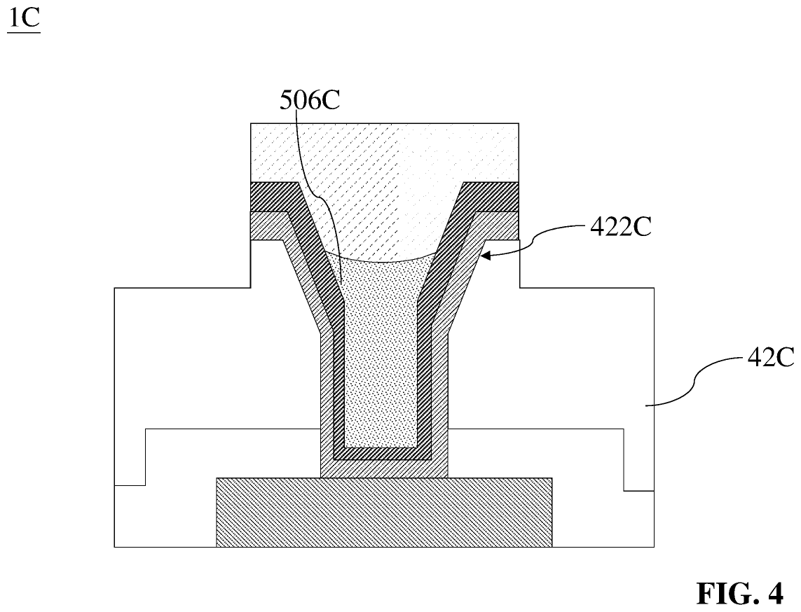

FIG. 4 is a vertical cross-sectional view of an enlarged region of a semiconductor device 1C according to some embodiments of the present disclosure. The semiconductor device 1C is similar to the semiconductor device 1A as described and illustrated with reference to FIGS. 1A, 1B and 1C, except that the conductive filling 506A is replaced by a conductive filling 506C. The conductive filling 506C is located at a position higher than the inclined surface 422C of the conductive layer 42C. That is, at least one portion of the inclined surface 422C of the conductive layer 42C is located at a position lower than the conductive filling 506C.

Based on the above description, in embodiments of the present disclosure, a portion of the dielectric layer is formed to have a chamfer structure. The chamfer structure can be conductive to alleviate the stress at the interface between the dielectric layer and the conductive via. As such, the stress distribution in the conductive via can be more uniform, and the probability of generating cracks can be reduced. Thus, the reliability of the semiconductor device can be enhanced, and the contact resistance thereof can be reduced.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a gate electrode disposed above the second nitride-based semiconductor layer; and
a first dielectric layer disposed above the gate electrode and having a top surface, a side surface and an inclined surface, wherein the inclined surface connects the top surface to the side surface, and a connection interface between the inclined surface and the side surface is above the gate electrode.

2. The semiconductor device of claim 1, further comprising:
a conductive via penetrating the first dielectric layer to make contact with the gate electrode, wherein the conductive via covers the inclined surface of the first dielectric layer.

3. The semiconductor device of claim 2, wherein the conductive via comprises at least one conductive layer conformal with a profile constructed by the top surface, the inclined surface, and the side surface of the first dielectric layer.

4. The semiconductor device of claim 3, wherein the conductive layer has an inclined surface above the gate electrode.

5. The semiconductor device of claim 4, wherein the conductive via further comprises a conductive filling wrapped by the conductive layer and located at a position lower than the inclined surface of the conductive layer.

6. The semiconductor device of claim 5, further comprising a circuit layer disposed over the conductive via and making contact with the inclined surface of the conductive layer.

7. The semiconductor device of claim 6, wherein a contact interface formed between the circuit layer and the conductive filling is located at a position lower than the inclined surface of the conductive layer.

8. The semiconductor device of claim 3, wherein the conductive via further comprises a conductive filling wrapped by the conductive layer, wherein the semiconductor device further comprises a circuit layer disposed over the conductive via and having a bottom portion in contact with the conductive filling.

9. The semiconductor device of claim 8, wherein the bottom portion has a pair of inclined surfaces in contact with the conductive via.

10. The semiconductor device of claim 1, wherein the side surface and the inclined surface have different extending depths.

11. The semiconductor device of claim 1, wherein the side surface and the inclined surface have different surface roughnesses.

12. The semiconductor device of claim 1, further comprising:
a second dielectric layer, disposed on the second nitride-based semiconductor layer and the gate electrode and located between the first dielectric layer and the second nitride-based semiconductor layer.

13. The semiconductor device of claim 1, wherein orthogonal projections of the side surface and the inclined surface on the second nitride-based semiconductor layer are within an orthogonal projection of the gate electrode on the second nitride-based semiconductor layer.

14. The semiconductor device of claim 1, wherein the inclined surface defines a first accommodating space, and a width of the first accommodating space gradually decreases along a direction from the top surface toward a bottom surface of the first dielectric layer.

15. The semiconductor device of claim 14, wherein the side surface defines a second accommodating space communicating with the first accommodating space, and a width of the second accommodating space is constant.

16. A method for manufacturing a semiconductor device, comprising:
forming a first nitride-based semiconductor layer;
forming a second nitride-based semiconductor layer on the first nitride-based semiconductor layer;
forming a gate electrode over the second nitride-based semiconductor layer; and
forming a first dielectric layer to cover the gate electrode and the second nitride-based semiconductor layer, wherein forming the first dielectric layer comprises:
forming a blanket dielectric layer to cover the gate electrode and the second nitride-based semiconductor layer;
patterning the blanket dielectric layer to form a through hole directly over the gate electrode; and
performing an ion bombardment process on a portion of the blanket dielectric layer adjacent to the through hole, such that the portion is formed to have an inclined surface, thereby forming the first dielectric layer.

17. The method of claim 16, wherein performing the ion bombardment process comprises emission of argon ions.

18. The method of claim 16, further comprises:
forming a plurality of conductive layers to conformally cover the portion of the first dielectric layer.

19. The method of claim 18, wherein the plurality of conductive layers comprises a first conductive layer and a second conductive layer, materials of the first and second conductive layers are different from each other, and the first conductive layer comprises titanium, and the second conductive layer comprises titanium nitride.

20. (canceled)

21. A nitride-based semiconductor device, comprising:
a first nitride-based semiconductor layer;
a second nitride-based semiconductor layer disposed on the first nitride-based semiconductor layer, wherein the second nitride-based semiconductor layer has a bandgap higher than a bandgap of the first nitride-based semiconductor layer;
a gate electrode disposed above the second nitride-based semiconductor layer and between a source electrode and a drain electrode; and
a first dielectric layer disposed above the gate electrode and having a chamfer structure that is located immediately over the gate electrode.

22-25. (canceled)
